(19) United States
(12) Patent Application Publication
(10) Pub. No.: US 2026/0239679 A1
(43) Pub. Date: Aug. 13, 2026

(54) SEMICONDUCTOR STRUCTURE AND FABRICATION METHOD THEREOF

(71) Applicant: NANYA TECHNOLOGY CORPORATION, New Taipei City (TW)

(72) Inventor: Ying-Cheng Chuang, New Taipei City (TW)

(73) Assignee: NANYA TECHNOLOGY CORPORATION, New Taipei City (TW)

(21) Appl. No.: 19/048,835

(22) Filed: Feb. 7, 2025

(51) Int. Cl. H10D 62/10; H01L 21/762; H10B 12/00

(52) U.S. Cl. CPC H10D 62/102; H10B 12/05; H10B 12/488; H10W 10/0145; H10W 10/17

(57) ABSTRACT

A semiconductor structure is provided. The semiconductor structure includes a substrate with active areas, shallow trench isolation (STI) structures disposed in the substrate, word lines embedded in the substrate, a first barrier layer, work function control structures, and a cap layer. Each word line includes active portions overlapping with corresponding ones of the active areas and passing portions overlapping with corresponding ones of the STI structures. The first barrier layer is disposed on top surfaces of the active portions and top surfaces of the passing portions. The work function control structures are disposed over the first barrier layer and the top surfaces of the active portions. The cap layer includes first portions and second portions. The first portions are located above the active portions. The second portions are located above the passing portions.

### BACKGROUND

### Technical Field

The present invention relates to a semiconductor structure and fabrication method thereof

### Description of Related Art

The buried word line (BWL) technology plays a crucial role in enhancing integration and performance in semiconductor memory, particularly in dynamic random-access memory (DRAM). By embedding the word line within the substrate, BWL not only effectively conserves surface space but also reduces capacitive coupling and interference between adjacent components, thereby improving overall signal integrity and power efficiency. However, as devices are further miniaturized, the fabrication process for BWL technology faces new challenges, one of which is the leakage issue caused by gate-induced drain leakage (GIDL).

The GIDL issue becomes more pronounced in highly integrated devices. With device miniaturization and the application of BWL technology, the GIDL phenomenon increasingly affects device stability, especially in high-density DRAM. When the gate voltage of a transistor increases, GIDL causes an increase in leakage current, which raises power consumption and undermines memory reliability. To address this problem, modern processes often use high-k dielectric materials or alternative structural designs to reduce leakage current, thereby supporting further miniaturization and performance optimization of BWL technology.

### SUMMARY

The present invention provides a semiconductor structure and a fabrication method thereof. In some embodiments of this disclosure, the work function control structures are positioned above the active portions of the word lines rather than above the passing portions. This a rrangement may reduce GIDL and provide the semiconductor structure with the advantage of faster word line turn-on.

In accordance of some embodiments of the present disclosure, a semiconductor structure includes a substrate with active areas, shallow trench isolation (STI) structures disposed in the substrate, word lines embedded in the substrate, a first barrier layer, work function control structures, and a cap layer. Each word line includes active portions overlapping with corresponding ones of the active areas and passing portions overlapping with corresponding ones of the STI structures. The first barrier layer is disposed on top surfaces of the active portions and top surfaces of the passing portions. The work function control structures are disposed over the first barrier layer and the top surfaces of the active portions. The cap layer includes first portions and second portions. The first portions are located above the active portions. The second portions are located above the passing portions. A length of the second portions extending into the substrate is longer than a length of the first portions extending into the substrate.

In some embodiments, a second barrier layer is disposed on top surfaces of the work function control structures and the first barrier layer. The cap layer is disposed over the second barrier layer.

In some embodiments, the second portions and the passing portions are embedded in the STI structures.

In some embodiments, the shallow trench isolation structures comprise an isolation material, and at least part of the shallow trench isolation structures further comprise a filling layer, wherein the isolation material comprises oxide, and the filling layer comprises nitride.

In some embodiments, each of the work function control structures includes a multilayered structure.

In accordance of some embodiments of the present disclosure, a fabrication method of a semiconductor structure comprises the following steps: providing a substrate with active areas and STI structures embedded in the substrate; forming word lines in the substrate, wherein each word line includes active portions overlapping with corresponding ones of the active areas and passing portions overlapping with corresponding ones of the STI structures; forming a first barrier layer on top surfaces of the active portions and top surfaces of the passing portions; forming a work function control material layer above the word lines; removing a portion of the work function control material layer over the passing portions, wherein remaining portions of the work function control material layer form work function control structures over the active portions; and forming a cap layer above the active portions and the passing portions.

In some embodiments, the cap layer includes first portions located above the active portions and second portions located above the passing portions. A length of the second portions extending into the substrate is longer than a length of the first portions extending into the substrate.

In some embodiments, a second barrier layer is formed on top surfaces of the work function control structures and the first barrier layer. The cap layer is formed over the second barrier layer.

In some embodiments, a chop mask layer is formed on the work function control material layer, wherein the chop mask layer includes openings that overlap the passing portions, and the chop mask layer is directly located above the active portions. The work function control material layer is etched by using the chop mask layer as a mask.

In some embodiments, each opening spans across the word lines.

### BRIEF DESCRIPTION OF THE DRAWINGS

FIGS. 1A to 1L are schematic cross-sectional views of the manufacturing method of a semiconductor structure of the embodiment of the present invention.

FIGS. 2A and 2B are perspective top views of the manufacturing method of a semiconductor structure of the embodiment of the present invention.

FIG. 3 is a schematic cross-sectional view of a semiconductor structure of the embodiment of the present invention.

FIG. 4 is a schematic cross-sectional view of a semiconductor structure of the embodiment of the present invention.

FIG. 5 is a schematic cross-sectional view of a semiconductor structure of the embodiment of the present invention.

FIGS. 6A to 6G are schematic cross-sectional views of a pitch doubling process of the embodiment of the present invention.

FIGS. 7A to 7D are schematic cross-sectional views of a pitch doubling process of the embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

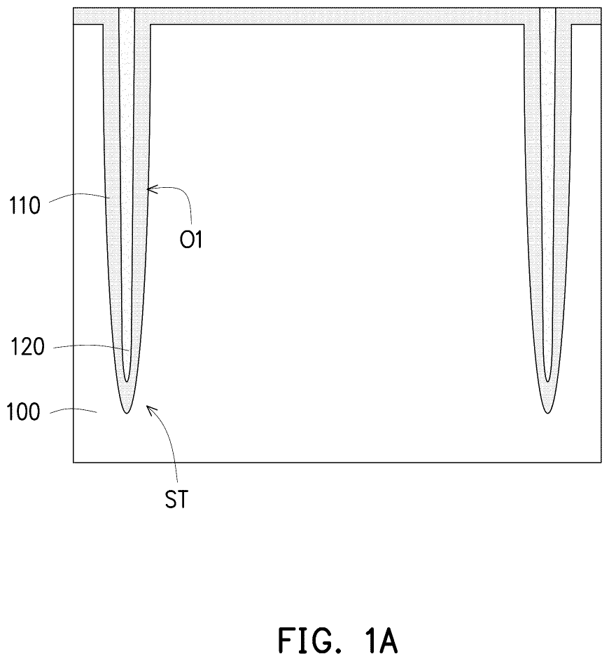

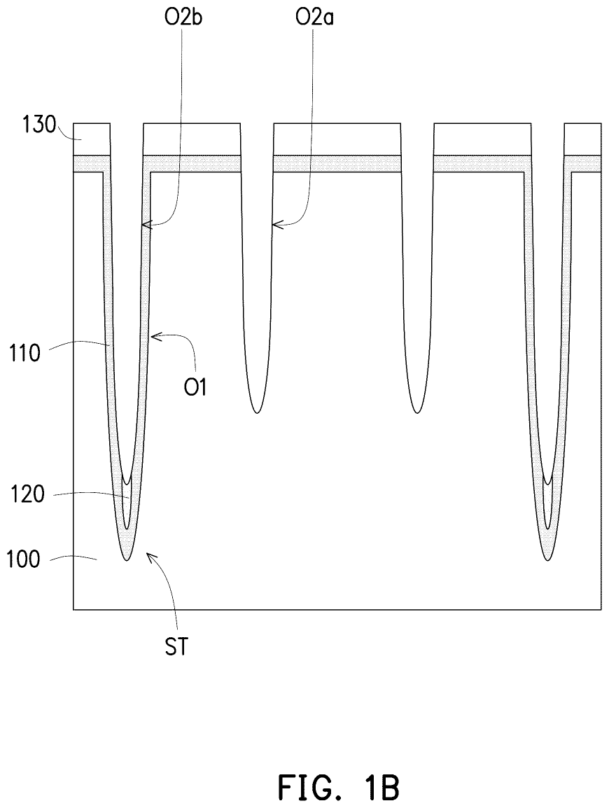

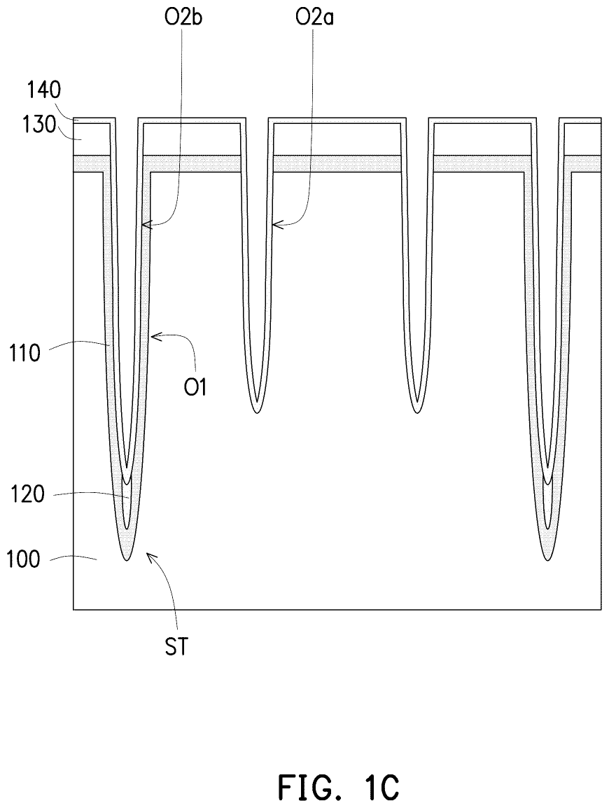

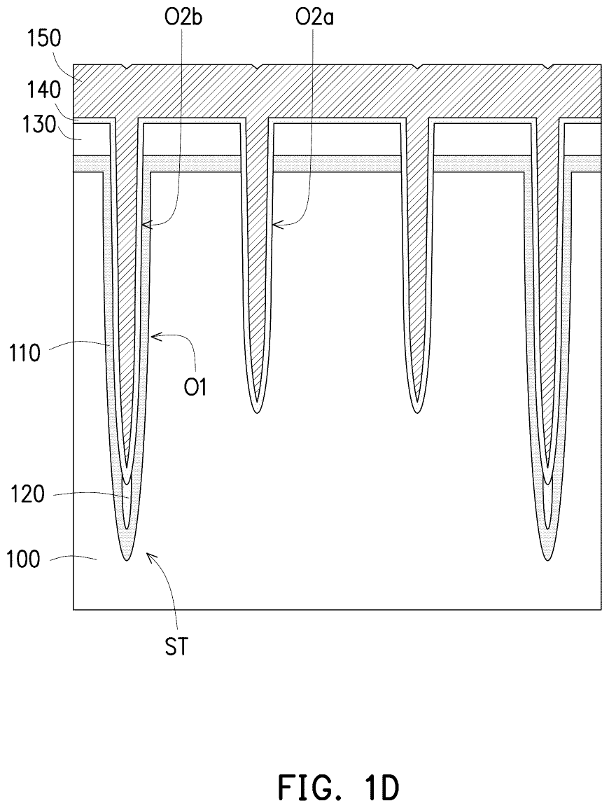

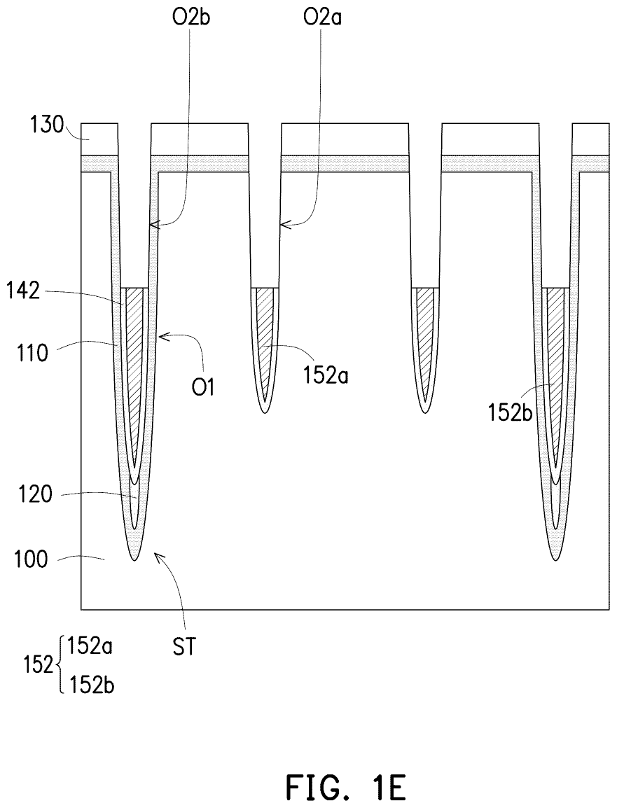

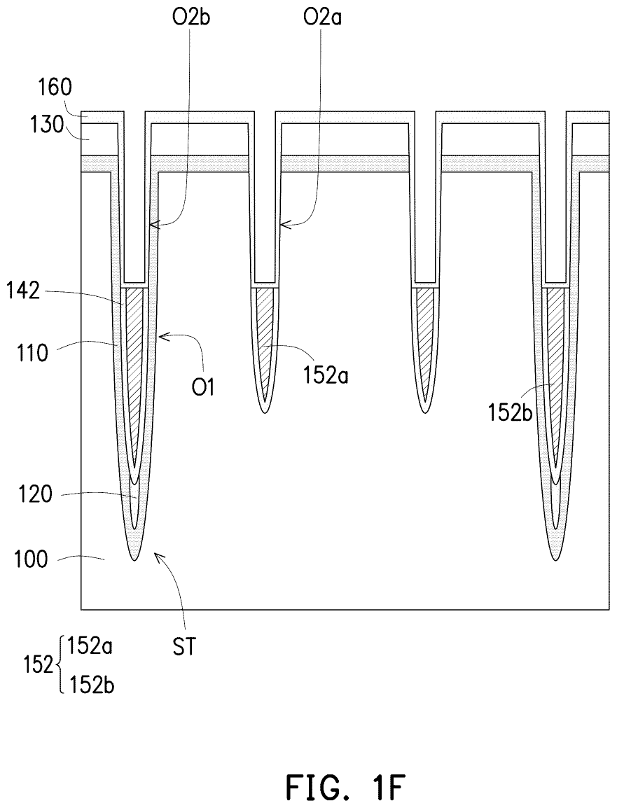

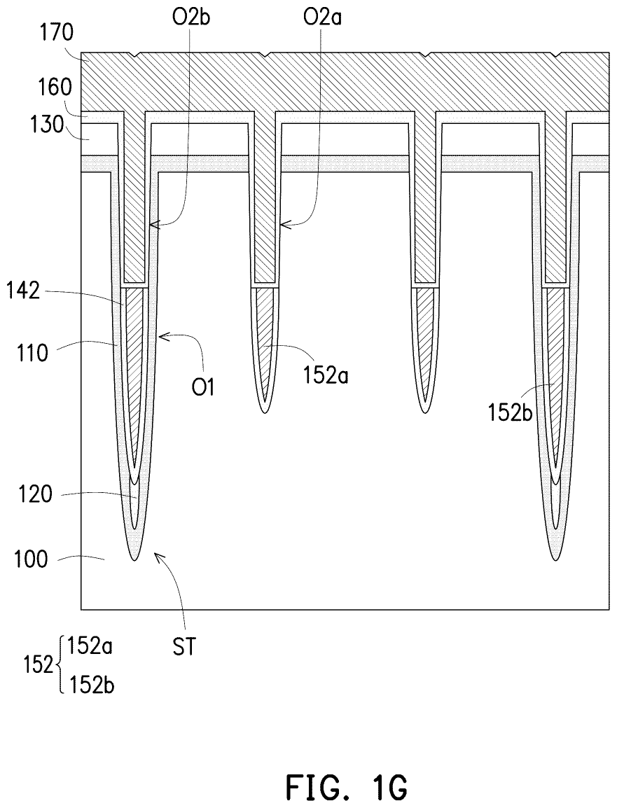

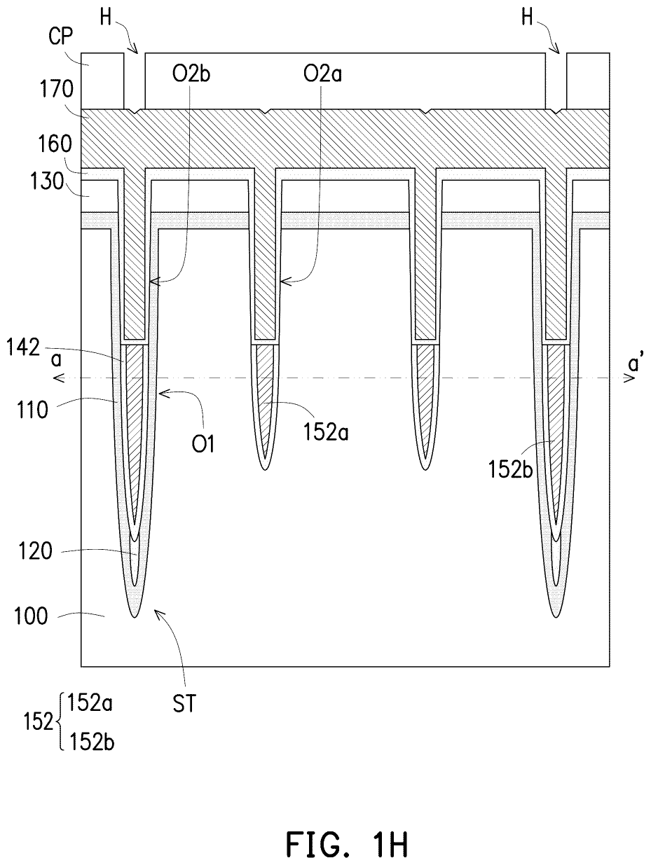

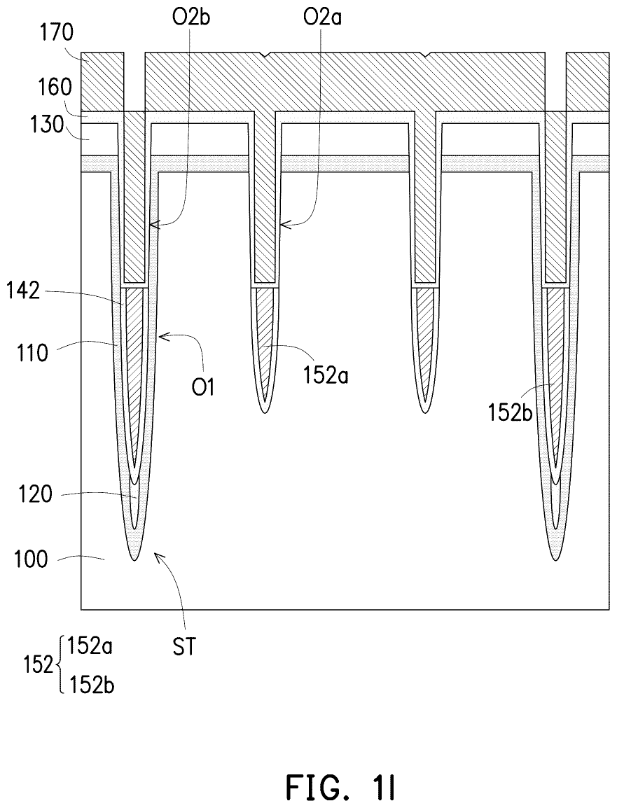

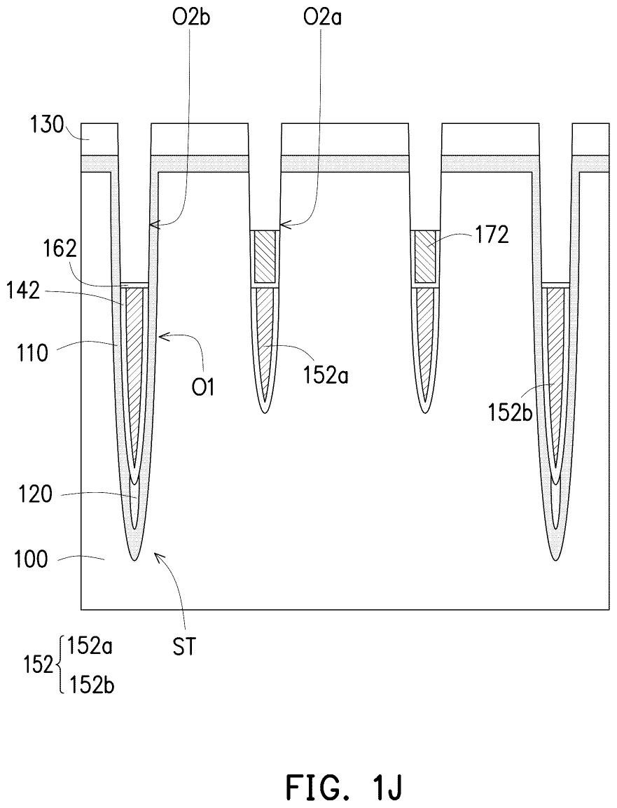

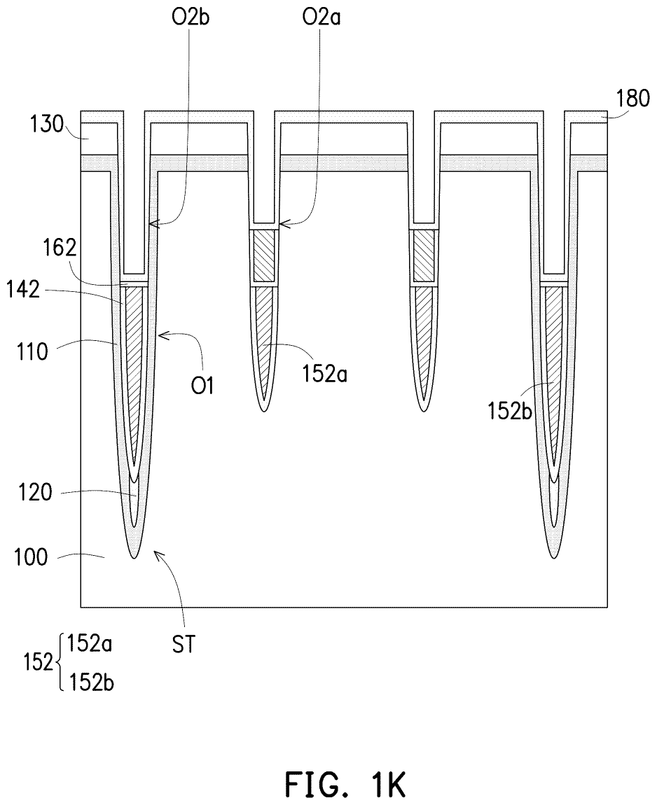

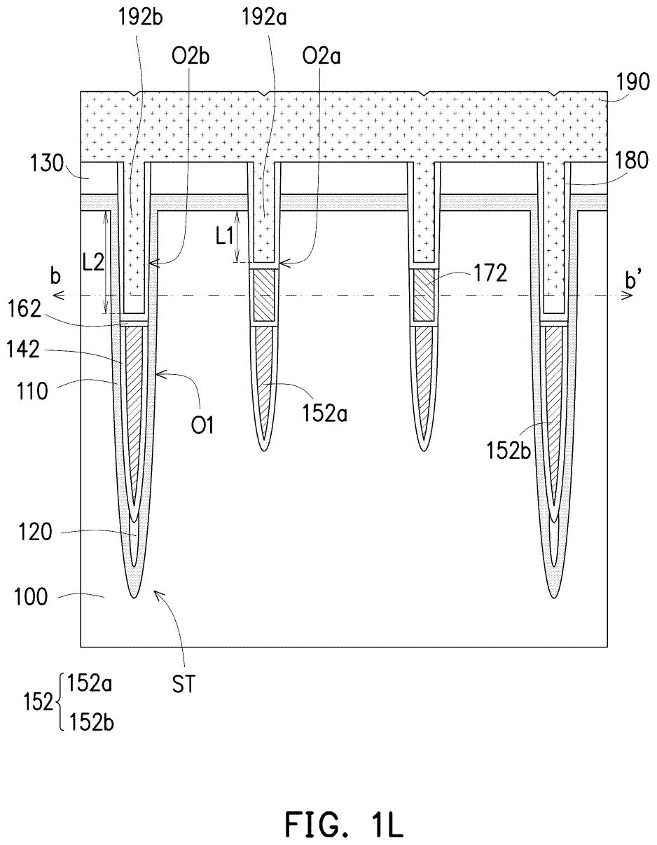

FIGS. 1A to 1L are schematic cross-sectional views of the manufacturing method of a semiconductor structure of the embodiment of the present invention. Referring to FIG. 1A, a substrate 100 is provided. The substrate 100 includes a semiconductor material, such as silicon, germanium, silicon carbide, gallium nitride, silicon-germanium, or other semiconductor materials.

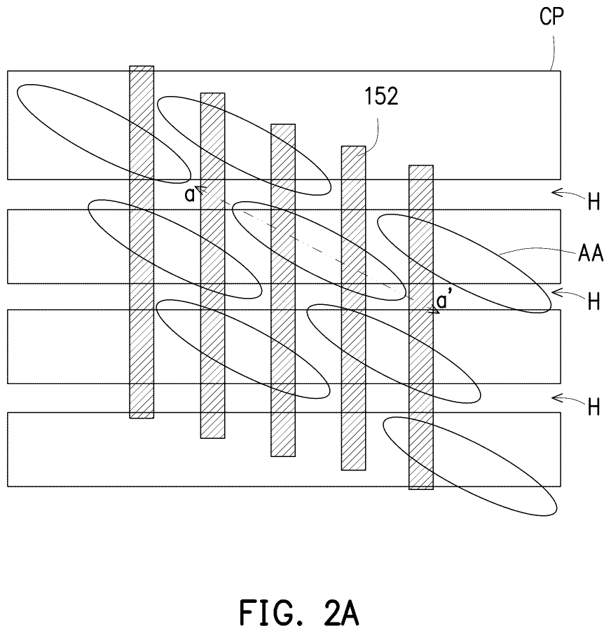

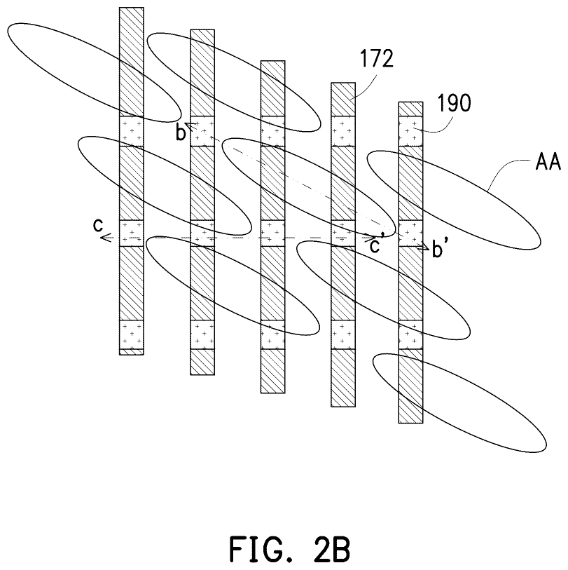

The substrate 100 includes active areas AA (not shown in FIG. 1A; refer to FIGS. 2A and 2B). The active areas AA are isolated from each other. Multiple first openings O1 are formed in the substrate 100. An isolation material 110 is filled into the first openings O1 to form shallow trench isolation (STI) structures ST embedded in the substrate 100. The STI structures ST are located between the active areas AA.

In some embodiments, when filling the first openings O1 with isolation material 110, each or part of the first openings O1 is not fully filled by the isolation material 110. In such cases, a filling layer 120 is used to occupy the remaining space in the first openings O1, and each or part of STI structure ST includes not only isolation material 110 but also the filling layer 120. In some embodiments, the isolation material 110 includes oxide, such as silicon oxide or other insulating materials. In some embodiments, the filling layer 120 includes nitride, such as silicon nitride or other insulating materials.

In some embodiments, the isolation material 110 not only disposed within the first openings O1 but also covers the top surface of the substrate 100; however, this disclosure is not limited thereto.

Referring to FIG. 1B, a mask layer 130 is formed above the substrate 100. In some embodiments, the mask layer 130 is formed on the isolation material 110. An etching process is performed on the substrate 100, during which the mask layer 130 is used to define multiple word line trenches, O2a and O2b. The word line trench O2b extends into the STI structures ST, while the word line trench O2a penetrates the isolation material 110 and extends into the substrate 100. Due to the different etching rates of the STI structures ST and the substrate 100, the depths of word line trenches O2a and O2b vary.

Referring to FIG. 1C, a gate dielectric material layer 140 is formed on the mask layer 130 and along the sidewalls of the word line trenches O2a and O2b. The gate dielectric material layer 140 may be deposited using one or more techniques, such as atomic layer deposition (ALD), in-situ steam generation (ISSG), or other suitable methods. In some embodiments, to minimize the residual stress associated with the gate dielectric material layer 140, a blanket oxide layer is first deposited using ALD, which results in lower residual stress. This oxide layer is then thickened using ISSG to achieve the desired final thickness for the gate dielectric material layer 140. In some embodiments, the gate dielectric material layer 140 includes oxide, such as silicon oxide; however, the present disclosure is not limited thereto. In other embodiments, the gate dielectric material layer 140 may include silicon nitride, silicon oxynitride, hafnium oxide, zirconium oxide, aluminum oxide, or other insulating materials with a dielectric constant higher than that of silicon oxide.

Referring to FIGS. 1D and 1E, word lines 152 are formed within the word line trenches O2a and O2b in the substrate 100. First, a conductive material 150 is deposited into the word line trenches O2a and O2b and on the gate dielectric layer 140, as shown in FIG. 1D. In some embodiments, the conductive material 150 includes aluminum (Al), copper (Cu), tungsten (W), titanium (Ti), tantalum (Ta), titanium-aluminum alloy (TiAl), titanium aluminum nitride (TiAlN), tantalum carbide (TaC), tantalum carbonitride (TaCN), tantalum silicon nitride (TaSiN), manganese (Mn), zirconium (Zr), titanium nitride (TiN), tungsten nitride (WN), tantalum nitride (TaN), ruthenium (Ru), titanium silicon nitride (TiSiN), other suitable materials, or combinations thereof. Next, in FIG. 1E, the conductive material 150 is etched to remove the excess material outside of the word line trenches O2a and O2b, forming the word lines 152, with a recess formed above the word lines 152. In some embodiments, while etching the conductive material 150, a portion of the gate dielectric layer 140 on the mask layer 130 is removed, leaving gate dielectric layers 142 along the sidewalls of the word lines 152. In this embodiment, the top surfaces of the gate dielectric layers 142 are aligned with the top surfaces of the word lines 152; however, this disclosure is not limited thereto. In other embodiments, the top surfaces of the gate dielectric layers 142 are positioned above the top surfaces of the word lines 152. In other words, the gate dielectric layers 142 extend beyond the top surfaces of the word lines 152.

In this embodiment, each word line 152 includes multiple active portions 152a in the word line trenches O2a and multiple passing portions 152b in the word line trenches O2b. The active portions 152a and passing portions 152b are connected and arranged alternately (for example, extending in a direction out of the plane of FIG. 1E). The active portions 152a overlap with corresponding active areas AA (not shown in FIG. 1E; refer to FIGS. 2A and 2B), while the passing portions 152b overlap with corresponding shallow trench isolation structures ST. In this embodiment, the depth of the passing portions 152b extending into the substrate 100 is greater than the depth of the active portions 152a extending into the substrate 100.

In some embodiments, after forming the word lines 152, a cleaning process is performed to remove residues generated during etching.

Referring to FIG. 1F, a first barrier material layer 160 is formed on the top surfaces of the active portions 152a and the top surfaces of the passing portions 152b. Specifically, the first barrier material layer 160 extends from the top surface of the mask layer 130 into the word line trenches O2a and O2b, covering the recessed areas on the tops of the active portions 152a and passing portions 152b. In some embodiments, the first barrier material layer 160 comprises an oxide, such as silicon oxide, silicon oxynitride, or other low k dielectric material. In some embodiments, the first barrier material layer 160 may be composed of a high-k dielectric material (e.g., silicon nitride); however, this is not intended to limit the scope of the present disclosure. The term “high dielectric constant” here is relative to that of silicon dioxide (κ=3.9), with silicon nitride exhibiting a κ value of 7 to 8. Employing a high-k dielectric material for the first barrier material layer 160 can help prevent excessive reductions in saturation current. In some embodiments, the first barrier material layer 160 is formed through atomic layer deposition (ALD) or other suitable methods.

Referring to FIG. 1G, a work function control material layer 170 is formed on the first barrier material layer 160. In this embodiment, the work function control material layer 170 fills the remaining portions of the word line trenches O2a and O2b. In some embodiments, the material selected for the work function control material layer 170 has a work function lower than that of the material used for the word lines 152. For example, the work function control material layer 170 may include a semiconductor material such as polysilicon. In some embodiments, the first barrier material layer 160 optionally has openings (not shown in the figures), through which the work function control material layer 170 contacts the word lines 152 beneath the first barrier material layer 160.

Referring to FIG. 1H and FIG. 2A, FIG. 2A shows a cross-sectional schematic corresponding to the position along line a-a′ in FIG. 1H, illustrating the word lines 152 and the active areas AA of the substrate 100. Additionally, FIG. 2A depicts the position of a chop mask layer CP to demonstrate the relative arrangement between the chop mask layer CP and the word lines 152. The chop mask layer CP is formed on the work function control material layer 170. In some embodiments, the chop mask layer CP may be a hard mask with a single-layer or multi-layer structure, or it may be a patterned photoresist layer. In embodiments where the chop mask layer CP is a hard mask, a mask material layer is first deposited, followed by the formation of a patterned photoresist layer on top. The mask material layer is then etched to create the chop mask layer CP. In some embodiments, the chop mask layer CP may be formed using a pitch doubling process; however, this disclosure is not limited thereto. The chop mask layer CP includes openings H that overlap the passing portions 152b, and the chop mask layer CP is positioned directly above the active portions 152a. Each of the openings H spans across multiple word lines 152.

Referring to FIGS. 1I and 1J, the work function control material layer 170 is etched using the chop mask layer CP as a mask. In some embodiments, after forming multiple recesses on the top surface of the work function control material layer 170 that overlap with the passing portions 152b, the chop mask layer CP is removed (e.g., through a strip process), as shown in FIG. 1I. Subsequently, an etching process is performed to remove a portion of the work function control material layer 170 above the passing portions 152b, leaving remaining portions of the work function control material layer 170 to form work function control structures 172 over the active portions 152a. In some embodiments, during the etching process to form the work function control structures 172, the first barrier material layer 160 is also etched, leaving a remaining portion called the first barrier layer 162 on the work function control structures 172. In some embodiments, the first barrier layer 162 covers the top surface of the passing portions 152b; however, this disclosure is not limited thereto. In other embodiments, the top surface of the passing portions 152b is exposed.

The work function control structures 172 are formed over the active portions 152a, creating buried dual work function gate electrodes within the active areas and helping to mitigate GIDL issues. Additionally, by removing the work function control material layer 170 above the passing portions 152b, the lateral electric field impact on the active portions 152a is reduced, thereby enhancing device performance in the long parallel select test (LPST).

Referring to FIG. 1K, a second barrier layer 180 is formed on the top surfaces o work function control structures 172 and the first barrier layer 162. In some embodiments, the second barrier layer 180 includes an oxide, such as silicon oxide, silicon oxynitride, or other low k dielectric materials. In some embodiments, the second barrier layer 180 may be composed of a high-k dielectric material (e.g., silicon nitride); however, this is not intended to limit the scope of the present disclosure. In some embodiments, the second barrier layer 180 is formed through atomic layer deposition (ALD) or other suitable methods.

Referring to FIGS. 1L and 2B, FIG. 2B shows a cross-sectional schematic corresponding to the position along line b-b′ in FIG. 1L, illustrating the work function control structures 172, a cap layer 190 and the active areas AA of the substrate 100. The cap layer 190 is formed above both the active portions 152a and the passing portions 152b. In some embodiments, before forming the cap layer 190, the second barrier layer 180 is etched (e.g., through dry etching or another suitable method) to expose the top surface of the mask layer 130, allowing the subsequently formed cap layer 190 to make contact with the mask layer 130. In certain embodiments, the mask layer 130 may be etched during any of the aforementioned etching processes, which could result in the top structure of the mask layer 130 not being flat as shown in the figures. For example, in some embodiments, the mask layer 130 may have a curved top surface.

In some embodiments, the cap layer 190 includes first portions 192a and second portions 192b. The first portions 192a are positioned above the active portions 152a and fill the word line trenches O2a. The second portions 192b are located above the passing portions 152b and fill the word line trenches O2b. The second portions 192b and the passing portions 152b are embedded in the STI structures ST. The length L2 of the second portions 192b extending into the substrate 100 is greater than the length L1 of the first portions 192a extending into the substrate 100.

In some embodiments, the cap layer 190 includes nitrides such as silicon nitride, but the disclosure is not limited thereto. In other embodiments, the cap layer 190 may include oxides such as silicon oxide or other insulating materials. In this embodiment, the cap layer 190 is separated from the work function control structures 172 and the passing portions 152b by the second barrier layer 180, but the disclosure is not limited thereto. In other embodiments, the second barrier layer 180 may be omitted, and the cap layer 190 may directly contact the work function control structures 172 and the passing portions 152b.

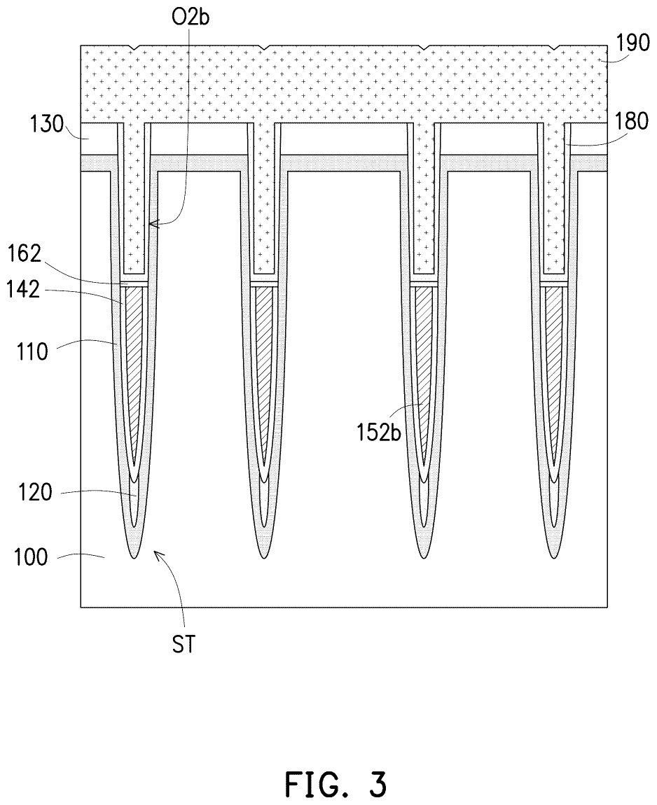

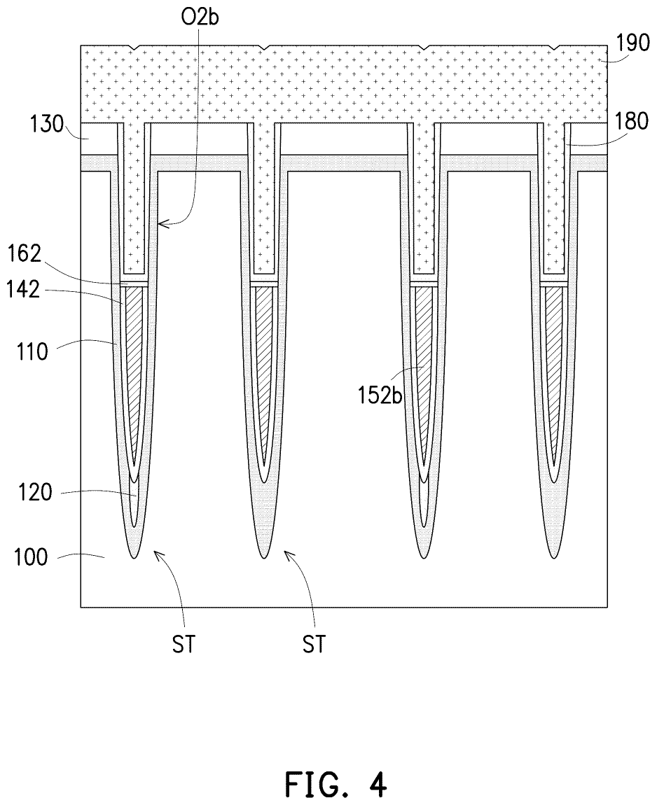

FIG. 3 is a schematic cross-sectional view of a semiconductor structure in an embodiment of the present invention. FIG. 3 corresponds to the position of line c-c′ in FIG. 2B. Referring to FIG. 3, in this embodiment, each STI structure ST includes the filling layer 120, but the disclosure is not limited to this. As shown in FIG. 4, in some embodiments, some STI structures ST do not include the filling layer 120.

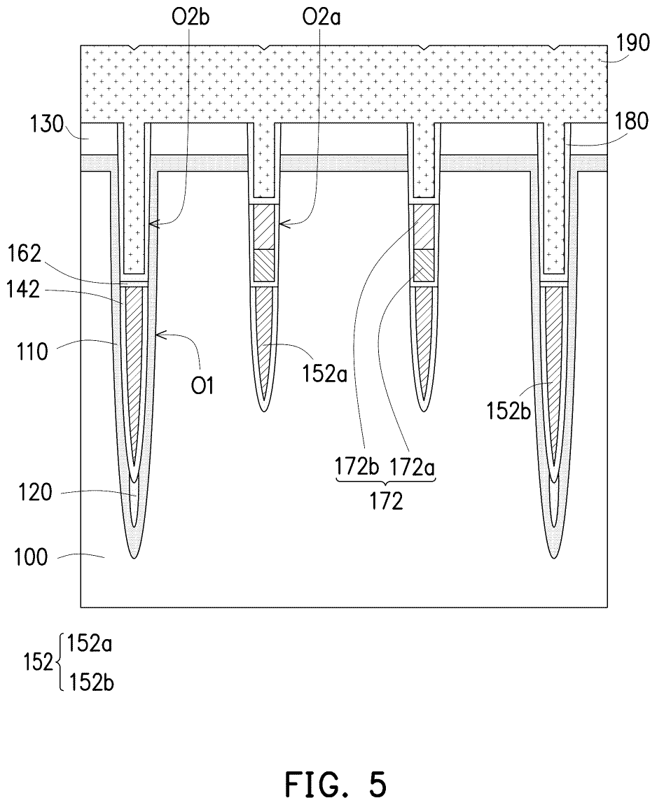

FIG. 5 is a schematic cross-sectional view of a semiconductor structure in one embodiment of the present invention. The embodiment in FIG. 5 is similar to the embodiment shown in FIGS. 1A to 1L, with the difference being that, in the embodiment of FIG. 5, the work function control structures 172 comprise a multilayered structure. Referring to FIG. 5, the work function control structures 172 include a first work function layer 172a and a second work function layer 172b. In some embodiments, both the first work function layer 172a and the second work function layer 172b include polysilicon, but with different doping concentrations. The first work function layer 172a, located at the bottom, has a higher doping concentration to ensure that the capacitor may charge quickly, while the second work function layer 172b, located at the top, has a lower doping concentration to improve GIDL.

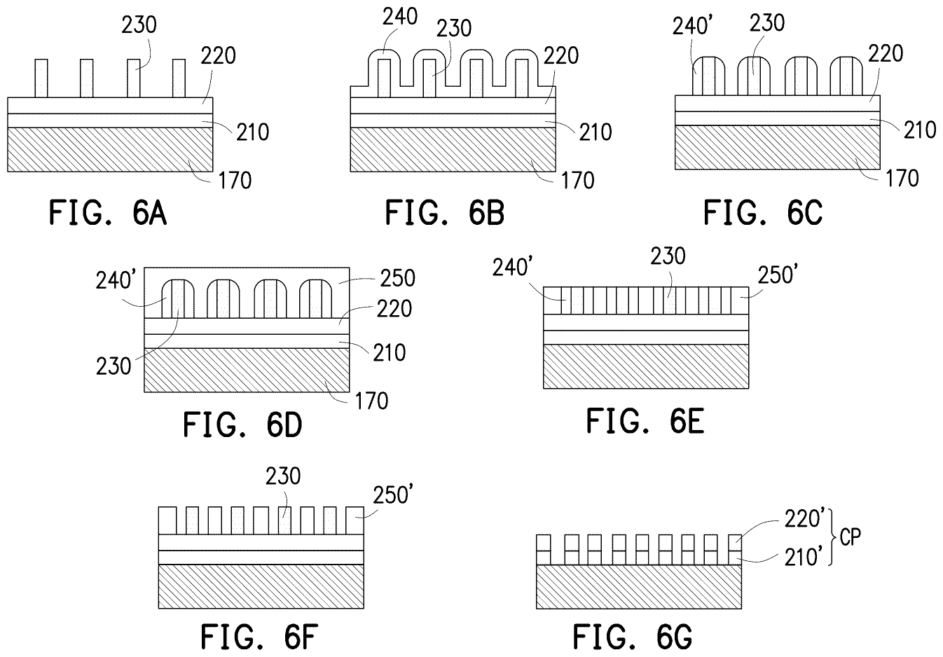

FIGS. 6A to 6G are schematic cross-sectional views of a pitch doubling process in one embodiment of the present invention. For example, the pitch doubling process shown in FIGS. 6A to 6G may be used to form the chop mask layer CP in FIG. 1H. Referring to FIG. 6A, an ashable hard mask layer 210 and an anti-reflective layer (ARL) 220 are formed on the work function control material layer 170. A patterned photoresist layer 230 is then formed on top of the ARL 220.

Referring to FIG. 6B, an oxide layer 240 is conformally formed on the patterned photoresist layer 230. Referring to FIG. 6C, the oxide layer 240 is etched to form spacers 240′.

Referring to FIG. 6D, a planarization film 250 is formed to cover the spacers 240′ and the patterned photoresist layer 230. Referring to FIG. 6E, an etching back process is used to remove part of the planarization film 250, exposing the patterned photoresist layer 230. The remaining portions of the planarization film 250 forms the mask 250′.

Referring to FIG. 6F, the spacers 240′ are removed, leaving the mask 250′ and the patterned photoresist layer 230. Referring to FIG. 6G, the ashable hard mask layer 210 and the ARL 220 are etched using the mask 250′ and the patterned photoresist layer 230′ to form the chop mask layer CP. The chop mask layer CP includes a patterned ashable hard mask layer 210′ and a patterned ARL 220′.

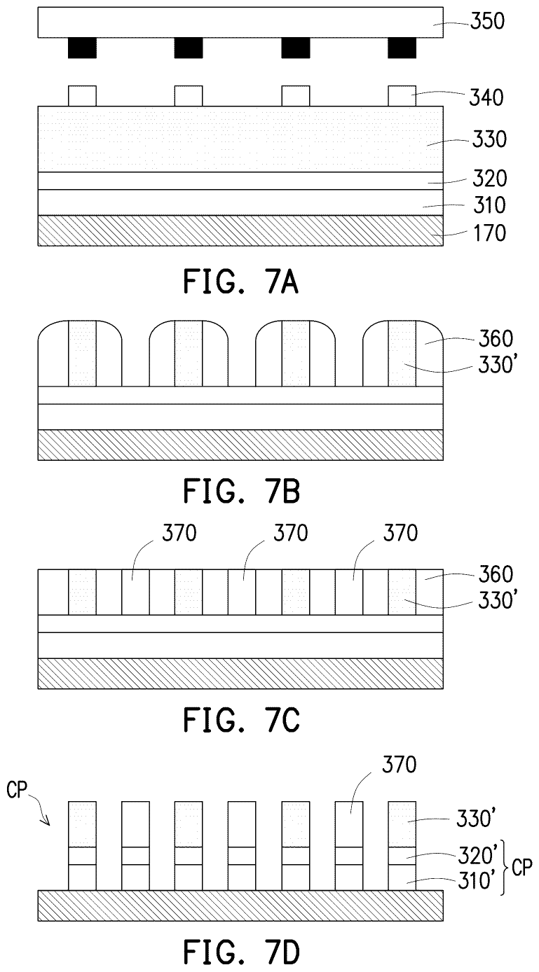

FIGS. 7A to 7D are schematic cross-sectional views of a pitch doubling process in another embodiment of the present invention. For example, the pitch doubling process shown in FIGS. 7A to 7D can be used to form the chop mask layer CP in FIG. 1H. Referring to FIG. 7A, a bottom hard mask layer 310, a buffer oxides layer 320, and a top hard layer 330 are formed on the work function control material layer 170. A patterned photoresist layer 340 is then formed on the top hard layer 330. For example, a patterned photoresist layer 340 is defined using a photomask 350.

Referring to FIG. 7B, the patterned photoresist layer 340 is used as a mask to etch the top hard layer 330, forming spacers 360 on the sidewalls of the patterned top hard layer 330′.

Referring to FIG. 7C, an oxide layer 370 is filled between the spacers 360, followed by a chemical mechanical polishing (CMP) process.

Referring to FIG. 7D, the spacers 360 are removed, and the oxide layer 370 and the etched top hard layer 330′ are used as a mask to etch the buffer oxide layer 320 and the bottom hard mask layer 310 to form the chop mask layer CP. The chop mask layer CP includes a patterned bottom hard mask layer 310′ and a patterned buffer oxide layer 320′.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate with a plurality of active areas;
a plurality of shallow trench isolation structures, disposed in the substrate;
a plurality of word lines, embedded in the substrate, wherein each word line comprises a plurality of active portions overlapping with corresponding ones of the plurality of active areas and a plurality of passing portions overlapping with corresponding ones of the plurality of shallow trench isolation structures;
a first barrier layer, disposed on top surfaces of the plurality of active portions and top surfaces of the plurality of passing portions;
a plurality of work function control structures, disposed over the first barrier layer and the top surfaces of the active portions; and
a cap layer, comprising:
a plurality of first portions, located above the plurality of active portions; and
a plurality of second portions, located above the plurality of passing portions, wherein a length of the plurality of second portions extending into the substrate is longer than a length of the plurality of first portions extending into the substrate.

2. The semiconductor structure of claim 1, further comprises
a second barrier layer, disposed on top surfaces of the plurality of work function control structures and the first barrier layer, wherein the cap layer is disposed over the second barrier layer.

3. The semiconductor structure of claim 1, wherein the plurality of second portions and the plurality of passing portions are embedded in the plurality of shallow trench isolation structures.

4. The semiconductor structure of claim 3, wherein the plurality of shallow trench isolation structures comprise an isolation material, and at least part of the plurality of shallow trench isolation structures further comprise a filling layer, wherein the isolation material comprises oxide, and the filling layer comprises nitride.

5. The semiconductor structure of claim 1, wherein each of the plurality of work function control structures comprises a multilayered structure.

6. A fabrication method of a semiconductor structure, comprising:
providing a substrate with a plurality of active areas and a plurality of shallow trench isolation structures embedded in the substrate;
forming a plurality of word lines in the substrate, wherein each word line comprises a plurality of active portions overlapping with corresponding ones of the plurality of active areas and a plurality of passing portions overlapping with corresponding ones of the plurality of shallow trench isolation structures;
forming a first barrier layer on top surfaces of the plurality of active portions and top surfaces of the plurality of passing portions;
forming a work function control material layer above the plurality of word lines;
removing a portion of the work function control material layer over the plurality of passing portions, wherein remaining portions of the work function control material layer form a plurality of work function control structures over the plurality of active portions; and
forming a cap layer above the plurality of active portions and the plurality of passing portions.

7. The fabrication method of claim 6, wherein the cap layer comprises:
a plurality of first portions, located above the plurality of active portions; and
a plurality of second portions, located above the plurality of passing portions, wherein a length of the plurality of second portions extending into the substrate is longer than a length of the plurality of first portions extending into the substrate.

8. The fabrication method of claim 6, further comprising:
forming a second barrier layer on top surfaces of plurality of work function control structures and the first barrier layer; and
forming the cap layer over the second barrier layer.

9. The fabrication method of claim 6, further comprising:
forming a chop mask layer on the work function control material layer, wherein the chop mask layer comprises a plurality of openings that overlap the plurality of passing portions, and the chop mask layer is directly located above the plurality of active portions; and
etching the work function control material layer by using the chop mask layer as a mask.

10. The fabrication method of claim 9, wherein each of the plurality of openings spans across the plurality of word lines.
